(19) United States
(12) Patent Application Publication
(10) Pub. No.: US 2017/0199251 A1
(43) Pub. Date: Jul. 13, 2017

(54) MAGNETISM MEASURING DEVICE, GAS CELL, MANUFACTURING METHOD OF MAGNETISM MEASURING DEVICE, AND MANUFACTURING METHOD OF GAS CELL

(71) Applicant: SEIKO EPSON CORPORATION, Tokyo (JP)

(72) Inventors: Eiichi FUJII, Shiojiri-shi (JP); Kimio NAGASAKA, Hokuto-shi (JP)

(73) Assignee: SEIKO EPSON CORPORATION, Tokyo (JP)

(21) Appl. No.: 15/391,590

(22) Filed: Dec. 27, 2016

(30) Foreign Application Priority Data
Jan. 12, 2016 (JP) 2016-003290

(51) Int. Cl. G01R 33/032; G01R 33/00

(52) U.S. Cl. CPC G01R 33/032; G01R 33/0052

(57) ABSTRACT

A magnetism measuring device which measures a magnetic field, includes: a gas cell including a cell portion which includes a main chamber, a reservoir that communicates with the main chamber and has a longitudinal direction, and an opening that is provided in the longitudinal direction of the reservoir on a side opposite to the main chamber, a sealing portion which seals the opening, and an alkali metal gas filling the main chamber and the reservoir; and a holding portion provided in the reservoir along the longitudinal direction.

This application claims the benefit of Japanese Patent Application No. 2016-3290, filed on Jan. 12, 2016. The content of the aforementioned application is hereby incorporated by reference in its entirety.

### BACKGROUND

1. Technical Field

The present invention relates to a magnetism measuring device, a gas cell, a manufacturing method of a magnetism measuring device, and a manufacturing method of a gas cell.

2. Related Art

An optical pumping type magnetism measuring device which irradiates a gas cell, in which an alkali metal gas is sealed, with linearly polarized light and measures a magnetic field according to a rotation angle of a polarization plane is known. JP-A-2012-183290 discloses a magnetism measuring device provided with a gas cell, in which an ampoule containing an alkali metal sealed therein is accommodated in a reservoir (ampoule accommodation chamber), a through-hole is formed in a glass tube of the ampoule by irradiating the ampoule with laser light, and the alkali metal in the ampoule is vaporized to cause the vapor (gas) thereof to fill the inside of a main chamber from the reservoir via a communication hole.

However, for example, in a case where the ampoule is inserted through an opening provided in the reservoir to be accommodated in the reservoir and the opening is blocked and sealed by a sealing portion, during handling through a process of accommodating the ampoule to the sealing process or during sealing by the sealing portion, there is concern that the ampoule may come out from the reservoir through the opening. In addition, when the position of the ampoule varies individually and deviates from a position of irradiation with laser light during the irradiation of the ampoule with the laser light, or when the ampoule in the reservoir is unstable and the ampoule moves due to an impact caused by the laser light irradiation, there is concern that processing performed in a depth direction through the laser light irradiation may not proceed and the gas of the alkali metal may not be generated. In a case of these problems, a reduction in manufacturing yield or an increase in the number of manufacturing processes due to re-processing may be incurred.

As a member for generating an alkali metal gas, a form other than the ampoule described in JP-A-2012-183290 may also be considered.

### SUMMARY

An advantage of some aspects of the invention is that it provides a gas cell, a magnetism measuring device, and manufacturing methods thereof, in which a member for generating an alkali metal gas, such as an ampoule accommodated in a reservoir, can be prevented from coming out through an opening and is held in a stable state in the reservoir to reliably generate the alkali metal gas through laser light irradiation, a reduction in manufacturing yield or an increase in the number of manufacturing processes can be prevented, and productivity can be improved.

The invention can be implemented as the following forms or application examples.

### Application Example 1

A magnetism measuring device according to this application example measures a magnetic field, and includes: a gas cell including a cell portion which includes a first chamber, a second chamber that communicates with the first chamber and has a longitudinal direction, and an opening that is provided in the longitudinal direction of the second chamber on a side opposite to the first chamber, a sealing portion which seals the opening, a gas of an alkali metal filling the first chamber and the second chamber; and a holding portion provided in the second chamber along the longitudinal direction.

According to the configuration of this application example, in the cell portion, the opening is provided in the longitudinal direction of the second chamber on the side opposite to the first chamber, and the holding portion is provided in the second chamber along the longitudinal direction. Therefore, a member for generating the alkali metal gas (hereinafter, sometimes simply referred to as a member), which is inserted into the second chamber along the longitudinal direction through the opening in a manufacturing process of the magnetism measuring device, can be disposed in the holding portion. Accordingly, the member can be held in the second chamber by the holding portion, and during handling until the sealing of the opening by the sealing portion or during sealing the opening by the sealing portion, the member can be prevented from coming out from the second chamber through the opening. In addition, when the gas of the alkali metal is generated by irradiating the member with laser light, deviation of the member from a position of irradiation with the laser light or movement of the member due to an impact caused by the laser light irradiation can be prevented. Therefore, the alkali metal gas can be more reliably generated. As a result, a magnetism measuring device capable of preventing a reduction in manufacturing yield or an increase in the number of manufacturing processes and improving productivity can be provided.

### Application Example 2

In the magnetism measuring device according to the application example, it is preferable that the holding portion has an inclined surface inclined with respect to the longitudinal direction.

According to the configuration of this application example, since the holding portion has the inclined surface inclined with respect to the longitudinal direction of the second chamber, the member inserted into the second chamber along the longitudinal direction through the opening can be guided by the inclined surface and can be easily disposed in the holding portion.

### Application Example 3

In the magnetism measuring device according to the application example, it is preferable that the holding portion is formed as a recessed portion which is recessed in the longitudinal direction from a wall surface of an inner wall on a side on which the opening of the second chamber is provided.

According to the configuration of this application example, since a stepped portion is formed between the wall surface of the inner wall on the side on which the opening of the second chamber is provided and the recessed portion recessed in the longitudinal direction from the wall surface and the stepped portion functions as a barrier that defines the holding portion (recessed portion) in the second chamber along the longitudinal direction, the member can be held by the holding portion (recessed portion) in the second chamber in a stable state.

### Application Example 4

In the magnetism measuring device according to the application example, it is preferable that the holding portion is formed as a protruding portion which extends in the longitudinal direction from a wall surface of an inner wall on a side on which the opening of the second chamber is provided.

According to the configuration of this application example, since the protruding portion which extends in the longitudinal direction from the wall surface of the inner wall on the side on which the opening of the second chamber is provided functions as a barrier that defines the holding portion in the second chamber along the longitudinal direction, the member can be held by the holding portion (a portion defined by the protruding portion) in the second chamber in a stable state.

### Application Example 5

A gas cell according to this application example includes: a cell portion which includes a first chamber, a second chamber that communicates with the first chamber and has a longitudinal direction, and an opening that is provided in the longitudinal direction of the second chamber on a side opposite to the first chamber; a sealing portion which seals the opening; and a gas of an alkali metal filling the first chamber and the second chamber, in which a holding portion is provided in the second chamber along the longitudinal direction.

According to the configuration of this application example, in the cell portion, the opening is provided in the longitudinal direction of the second chamber on the side opposite to the first chamber, and the holding portion is provided in the second chamber along the longitudinal direction. Therefore, a member for generating the alkali metal gas, which is inserted into the second chamber along the longitudinal direction through the opening in a manufacturing process of the gas cell, can be disposed in the holding portion. Accordingly, the member can be held in the second chamber by the holding portion, and during handling until the sealing of the opening by the sealing portion or during sealing the opening by the sealing portion, the member can be prevented from coming out from the second chamber through the opening. In addition, when the gas of the alkali metal is generated by irradiating the member with laser light, deviation of the member from a position of irradiation with the laser light or movement of the member due to an impact caused by the laser light irradiation can be prevented. Therefore, the alkali metal gas can be more reliably generated. As a result, a gas cell capable of preventing a reduction in manufacturing yield or an increase in the number of manufacturing processes and improving productivity can be provided.

### Application Example 6

In the gas cell according to the application example, it is preferable that the holding portion has an inclined surface inclined with respect to the longitudinal direction.

According to the configuration of this application example, since the holding portion has the inclined surface inclined with respect to the longitudinal direction of the second chamber, the member inserted into the second chamber along the longitudinal direction through the opening can be guided by the inclined surface and can be easily disposed in the holding portion.

### Application Example 7

In the gas cell according to the application example, the holding portion may be formed as a recessed portion which is recessed in the longitudinal direction from a wall surface of an inner wall on a side on which the opening of the second chamber is provided.

According to the configuration of this application example, since a stepped portion is formed between the wall surface of the inner wall on the side on which the opening of the second chamber is provided and the recessed portion recessed in the longitudinal direction from the wall surface and the stepped portion functions as a barrier that defines the holding portion (recessed portion) in the second chamber along the longitudinal direction, the member can be held by the holding portion (recessed portion) in the second chamber in a stable state.

### Application Example 8

In the gas cell according to the application example, the holding portion may be formed as a protruding portion which extends in the longitudinal direction from a wall surface of an inner wall on a side on which the opening of the second chamber is provided.

According to the configuration of this application example, since the protruding portion which extends in the longitudinal direction from the wall surface of the inner wall on the side on which the opening of the second chamber is provided functions as a barrier that defines the holding portion in the second chamber along the longitudinal direction, the member can be held by the holding portion (a portion defined by the protruding portion) in the second chamber in a stable state.

### Application Example 9

A manufacturing method of a magnetism measuring device which measures a magnetic field according to this application example includes: inserting a solid containing an alkali metal through an opening along a longitudinal direction to be disposed in a second chamber of a cell portion which includes a first chamber, the second chamber that communicates with the first chamber and has the longitudinal direction, a holding portion provided in the second chamber along the longitudinal direction, and an opening that is provided in the longitudinal direction of the second chamber on a side opposite to the first chamber; sealing the opening by a sealing portion; and irradiating the solid with laser light, in which the solid is disposed in the holding portion in the inserting of the solid.

According to the manufacturing method of this application example, in the inserting of the solid, the solid containing the alkali metal, which is a member for generating an alkali metal gas, is inserted, along the longitudinal direction, into the second chamber of the cell portion provided with the holding portion along the longitudinal direction, through the opening provided on the side opposite to the first chamber along the longitudinal direction, and is disposed in the holding portion. Accordingly, the solid can be held in the second chamber by the holding portion. Therefore, during handling through the inserting of the solid to the sealing of the opening, or during sealing of the opening by the sealing portion in the sealing of the opening, the solid can be prevented from coming out from the second chamber through the opening. In addition, when the gas of the alkali metal is generated by irradiating the solid with laser light in the irradiating of the solid, deviation of the solid from a position of irradiation with the laser light or movement of the solid due to an impact caused by the laser light irradiation can be prevented. Therefore, the alkali metal gas can be more reliably generated. As a result, a manufacturing method of a magnetism measuring device capable of preventing a reduction in manufacturing yield or an increase in the number of manufacturing processes and improving productivity can be provided.

### Application Example 10

In the manufacturing method of a magnetism measuring device according to the application example, it is preferable that in the sealing of the opening, the cell portion is disposed on the sealing portion such that the longitudinal direction follows a vertical direction and the opening is on a lower side in the vertical direction.

According to the manufacturing method of this application example, since the cell portion is disposed on the sealing portion so as to cause the opening to be on the lower side in the vertical direction in the sealing of the opening, for example, in a case where the sealing portion and the cell portion are fixed to each other by low-melting-point glass as a sealing material, sealing can be efficiently performed by applying a load onto the cell portion positioned on the upper side from the sealing portion side positioned on the lower side while heating the low-melting-point glass. At this time, since the solid is held in the holding portion, even when the cell portion is disposed so as to cause the opening to be on the lower side, the solid can be prevented from coming out from the second chamber through the opening.

### Application Example 11

In the manufacturing method of a magnetism measuring device according to the application example, it is preferable that the solid is an ampoule filled with an alkali metal material, and in the irradiating of the solid, the ampoule is irradiated with pulsed laser light with a wavelength in the ultraviolet region.

According to the manufacturing method of this application example, since the ampoule filled with the alkali metal material is irradiated with the pulsed laser light with a wavelength in the ultraviolet region in the irradiating of the solid, a through-hole can be formed in a glass tube of the ampoule without damage to the cell portion and thus the alkali metal therein can be vaporized to generate the alkali metal gas. In addition, since the ampoule is held in the holding portion when the pulsed laser light is emitted, deviation of the ampoule from a position of irradiation with the pulsed laser light or movement of the ampoule due to an impact caused by the pulsed laser light irradiation can be prevented.

### Application Example 12

In the manufacturing method of a magnetism measuring device according to the application example, it is preferable that the solid is a pill containing an alkali metal compound and an adsorbent, and in the irradiating of the solid, the pill is irradiated with continuous oscillating laser light with a wavelength in the infrared region with the red end.

According to the manufacturing method of this application example, since the pill containing the alkali metal compound and the adsorbent is irradiated with the continuous oscillating laser light with a wavelength in the infrared region with the red end in the irradiating of the solid, the alkali metal gas can be generated by locally heating the pill and activating the alkali metal compound, and impurities can be adsorbed onto the adsorbent. In addition, since the pill is held in the holding portion when the continuous oscillating laser light is emitted, deviation of the pill from a position of irradiation with the continuous oscillating laser light or movement of the pill due to an impact caused by the continuous oscillating laser light can be prevented.

### Application Example 13

A manufacturing method of a gas cell according to this application example includes: inserting a solid containing an alkali metal through an opening along a longitudinal direction to be disposed in a second chamber of a cell portion which includes a first chamber, the second chamber that communicates with the first chamber and has the longitudinal direction, a holding portion provided in the second chamber along the longitudinal direction, and an opening that is provided in the longitudinal direction of the second chamber on a side opposite to the first chamber; sealing the opening by a sealing portion; and irradiating the solid with laser light, in which the solid is disposed in the holding portion in the inserting of the solid.

According to the manufacturing method of this application example, in the inserting of the solid, the solid containing the alkali metal, which is a member for generating an alkali metal gas, is inserted, along the longitudinal direction, into the second chamber of the cell portion provided with the holding portion along the longitudinal direction, through the opening provided on the side opposite to the first chamber along the longitudinal direction, and is disposed in the holding portion. Accordingly, the solid can be held in the second chamber by the holding portion. Therefore, during handling through the inserting of the solid to the sealing of the opening, or during sealing of the opening by the sealing portion in the sealing of the opening, the solid can be prevented from coming out from the second chamber through the opening. In addition, when the gas of the alkali metal is generated by irradiating the solid with laser light in the irradiating of the solid, deviation of the solid from a position of irradiation with the laser light or movement of the solid due to an impact caused by the laser light irradiation can be prevented. Therefore, the alkali metal gas can be more reliably generated. As a result, a manufacturing method of a gas cell capable of preventing a reduction in manufacturing yield or an increase in the number of manufacturing processes and improving productivity can be provided.

### Application Example 14

In the manufacturing method of a gas cell according to the application example, it is preferable that in the sealing of the opening, the cell portion is disposed on the sealing portion such that the longitudinal direction follows a vertical direction and the opening is on a lower side in the vertical direction.

According to the manufacturing method of this application example, since the cell portion is disposed on the sealing portion so as to cause the opening to be on the lower side in the vertical direction in the sealing of the opening, for example, in a case where the sealing portion and the cell portion are fixed to each other by low-melting-point glass as a sealing material, sealing can be efficiently performed by applying a load onto the cell portion positioned on the upper side from the sealing portion side positioned on the lower side while heating the low-melting-point glass. At this time, since the solid is held in the holding portion, even when the cell portion is disposed so as to cause the opening to be on the lower side, the solid can be prevented from coming out from the second chamber through the opening.

### Application Example 15

In the manufacturing method of a gas cell according to the application example, it is preferable that the solid is an ampoule filled with an alkali metal material, and in the irradiating of the solid, the ampoule is irradiated with pulsed laser light with a wavelength in the ultraviolet region.

According to the manufacturing method of this application example, since the ampoule filled with the alkali metal material is irradiated with the pulsed laser light with a wavelength in the ultraviolet region in the irradiating of the solid, a through-hole can be formed in a glass tube of the ampoule without damage to the cell portion and thus the alkali metal therein can be vaporized to generate the alkali metal gas. In addition, since the ampoule is held in the holding portion when the pulsed laser light is emitted, deviation of the ampoule from a position of irradiation with the pulsed laser light or movement of the ampoule due to an impact caused by the pulsed laser light irradiation can be prevented.

### Application Example 16

In the manufacturing method of a gas cell according to the application example, it is preferable that the solid is a pill containing an alkali metal compound and an adsorbent, and in the irradiating of the solid, the pill is irradiated with continuous oscillating laser light with a wavelength in the infrared region with the red end.

According to the manufacturing method of this application example, since the pill containing the alkali metal compound and the adsorbent is irradiated with the continuous oscillating laser light with a wavelength in the infrared region with the red end in the irradiating of the solid, the alkali metal gas can be generated by locally heating the pill and activating the alkali metal compound, and impurities can be adsorbed onto the adsorbent. In addition, since the pill is held in the holding portion when the continuous oscillating laser light is emitted, deviation of the pill from a position of irradiation with the continuous oscillating laser light or movement of the pill due to an impact caused by the continuous oscillating laser light can be prevented.

### BRIEF DESCRIPTION OF THE DRAWINGS

The invention will be described with reference to the accompanying drawings, wherein like numbers reference like elements.

FIG. 1 is a block diagram illustrating the configuration of a magnetism measuring device according to an embodiment.

FIG. 2A is a sectional side view of a gas cell according to a first embodiment along a longitudinal direction thereof.

FIG. 2B is a sectional plan view taken along line A-A′ of FIG. 2A.

FIG. 3A is side view when viewed from a sealing portion of the gas cell according to the first embodiment.

FIG. 3B is a sectional view of an ampoule according to the first embodiment along a longitudinal direction thereof.

FIG. 3C is a schematic cross-sectional view taken along line C-C′ of FIG. 3B.

FIG. 4A is a view illustrating a manufacturing method of the gas cell according to the first embodiment.

FIG. 4B is a view illustrating the manufacturing method of the gas cell according to the first embodiment.

FIG. 5A is a view illustrating the manufacturing method of the gas cell according to the first embodiment.

FIG. 5B is a view illustrating the manufacturing method of the gas cell according to the first embodiment.

FIG. 6A is a view illustrating the manufacturing method of the gas cell according to the first embodiment.

FIG. 6B is a view illustrating the manufacturing method of the gas cell according to the first embodiment.

FIG. 7A is a sectional side view of a gas cell according to a second embodiment along a longitudinal direction thereof.

FIG. 7B is a sectional plan view taken along line A-A′ of FIG. 7A.

FIG. 8A is a perspective view of a pill according to the second embodiment.

FIG. 8B is a view illustrating a manufacturing method of the gas cell according to the second embodiment.

FIG. 9A is a view illustrating the manufacturing method of the gas cell according to the second embodiment.

FIG. 9B is a view illustrating the manufacturing method of the gas cell according to the second embodiment.

FIG. 10A is a view illustrating the manufacturing method of the gas cell according to the second embodiment.

FIG. 10B is a view illustrating the manufacturing method of the gas cell according to the second embodiment.

FIG. 11A is a partial sectional plan view illustrating a configuration example of the gas cell according to Modification Example 1.

FIG. 11B is a partial sectional plan view illustrating the configuration example of the gas cell according to Modification Example 1.

FIG. 11C is a partial sectional plan view illustrating the configuration example of the gas cell according to Modification Example 1.

FIG. 12A is a sectional view illustrating a configuration example of the gas cell according to Modification Example 2.

FIG. 12B is a sectional view illustrating the configuration example of the gas cell according to Modification Example 2.

FIG. 12C is a sectional view illustrating the configuration example of the gas cell according to Modification Example 2.

FIG. 13 is a schematic view illustrating the configuration of an atomic oscillator according to Modification Example 3.

FIG. 14A is a view illustrating the operation of the atomic oscillator according to Modification Example 3.

FIG. 14B is a view illustrating the operation of the atomic oscillator according to Modification Example 3.

### DESCRIPTION OF EXEMPLARY EMBODIMENTS

Hereinafter, embodiments which embody the invention will be described with reference to the drawings. The drawings that are used are appropriately enlarged, reduced, or exaggerated to allow described parts to be recognizable. In addition, there may be a case where the illustration of constituent elements which are not necessary for description is omitted.

### First Embodiment

### Configuration of Magnetism Measuring Device

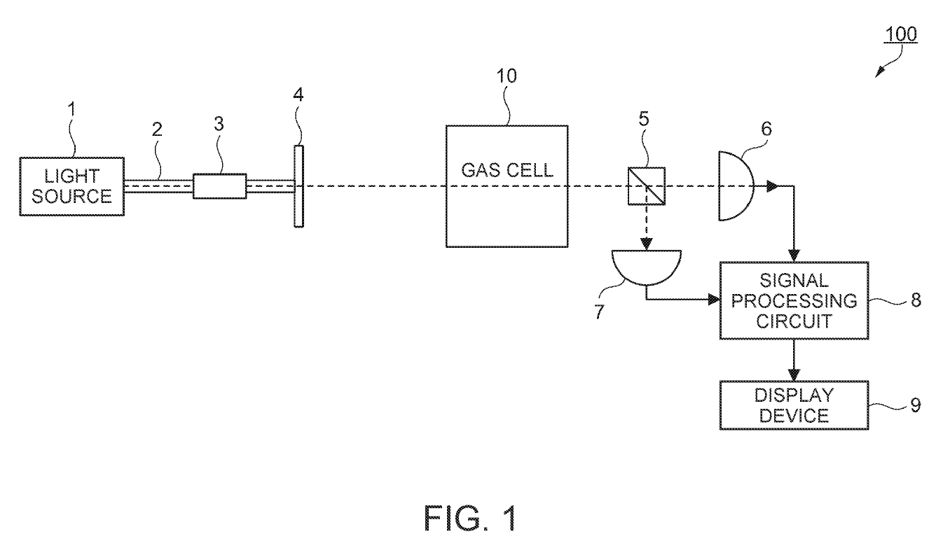

The configuration of a magnetism measuring device according to a first embodiment will be described with reference to FIG. 1. FIG. 1 is a block diagram illustrating the configuration of the magnetism measuring device according to this embodiment. A magnetism measuring device 100 according to this embodiment is a magnetism measuring device which uses nonlinear magneto-optical rotation (NMOR). The magnetism measuring device 100 is used in, for example, a living body state measuring device (magnetocardiography, magnetoencephalography, or the like) which measures a weak magnetic field generated from a living body such as a magnetic field from the heart (cardiac magnetism) or a magnetic field from the brain (cerebral magnetism). The magnetism measuring device 100 may also be used in a metal detector or the like.

As illustrated in FIG. 1, the magnetism measuring device 100 includes a light source 1, an optical fiber 2, a connector 3, a polarizing plate 4, a gas cell 10, a polarization splitter 5, a photodetector (PD) 6, a photodetector 7, a signal processing circuit 8, and a display device 9. An alkali metal gas (alkali metal atoms in a gas state) is sealed in the gas cell 10. As the alkali metal, for example, cesium (Cs), rubidium (Rb), potassium (K), or sodium (Na) may be used. In the following description, a case where cesium is used as the alkali metal is exemplified.

The light source 1 is a device which outputs a laser beam having a wavelength corresponding to the cesium absorption lines (for example, 894 nm corresponding to the Dl line), for example, a tunable laser. The laser beam output from the light source 1 is so-called continuous wave (CW) light having a continuously constant light intensity.

The polarizing plate 4 is an element which polarizes the laser beam in a specific direction into linearly polarized light. The optical fiber 2 is a member which guides the laser beam output from the light source 1 to the gas cell 10 side. As the optical fiber 2, for example, a single-mode optical fiber which propagates only a basic mode is used. The connector 3 is a member for connecting the optical fiber 2 to the polarizing plate 4. The connector 3 connects the optical fiber 2 to the polarizing plate 4 in a screw type.

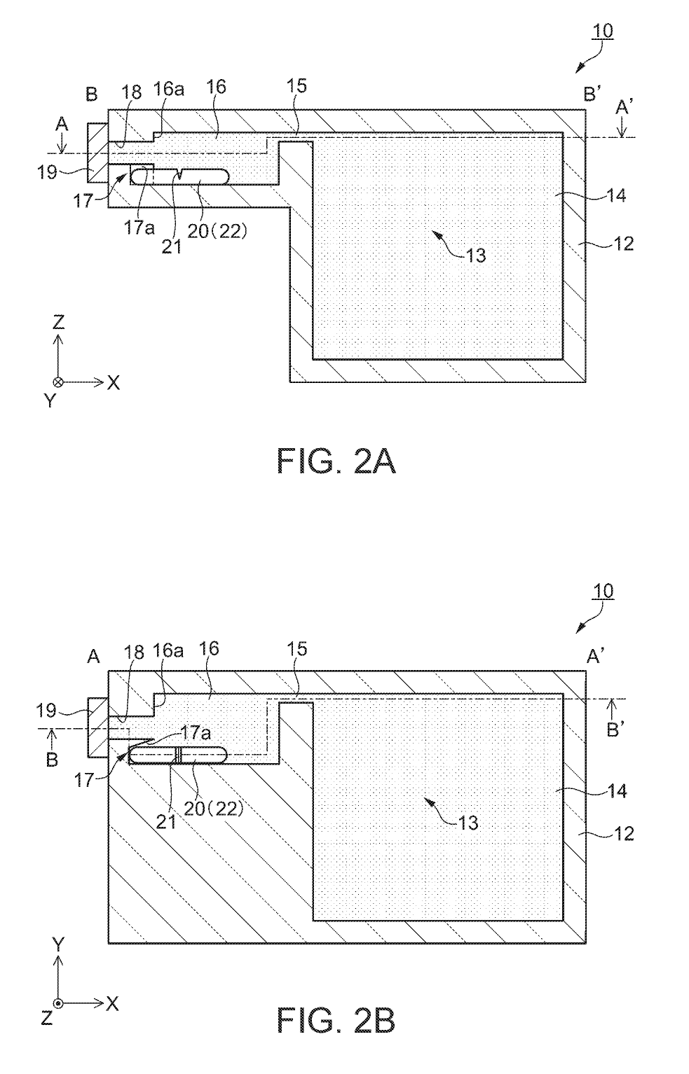

The gas cell 10 is a box (cell) having a void therein, and the vapor of the alkali metal (an alkali metal gas 13 illustrated in FIG. 2A) is sealed in the void (a main chamber 14 illustrated in FIG. 2A). The configuration of the gas cell 10 will be described later.

The polarization splitter 5 is an element which splits the incident laser beam into beams having two polarization components that are perpendicular to each other. The polarization splitter 5 is, for example, a Wollaston prism or a polarizing beam splitter. The photodetector 6 and the photodetector 7 are detectors having sensitivity to the wavelength of the laser beam, and output currents corresponding to the light intensity of the incident light to the signal processing circuit 8. If the photodetector 6 and the photodetector 7 generate magnetic fields, there is a possibility that the measurement may be affected. Therefore, it is preferable that the photodetector 6 and the photodetector 7 are formed of a non-magnetic material. The photodetector 6 and the photodetector 7 are disposed on the same side as that of the polarization splitter 5 (downstream side) when viewed from the gas cell 10.

The arrangement of the parts in the magnetism measuring device 100 will be described along the path of the laser beam. At the uppermost position in the path of the laser beam, the light source 1 is positioned. From the upstream side therebelow, the optical fiber 2, the connector 3, the polarizing plate 4, the gas cell 10, the polarization splitter 5, and the photodetectors 6 and 7 are arranged in this order.

The laser beam output from the light source 1 is guided to the optical fiber 2 and reaches the polarizing plate 4. The laser beam that reaches the polarizing plate 4 becomes linearly polarized light having higher polarization degree. The laser beam that passes through the gas cell 10 allows the alkali metal atoms sealed in the gas cell 10 to excite (optical pumping). At this time, the laser beam undergoes a polarization plane rotation action according to the intensity of a magnetic field such that the polarization plane is rotated. The laser beam that has passed through the gas cell 10 is split into beams having two polarization components by the polarization splitter 5. The light intensities of the beams having the two polarization components are measured by the photodetectors 6 and 7 (probing).

The signal processing circuit 8 receives signals indicating the light intensities of the beams measured by the photodetectors 6 and 7. The signal processing circuit 8 measures the rotation angle of the polarization plane of the laser beam on the basis of the received signals. The rotation angle of the polarization plane is expressed by a function based on the intensity of the magnetic field in the propagation direction of the laser beam (for example, refer to Expression (2) of “Resonant nonlinear magneto-optical effects in atoms” in Reviews of Modern Physics., APS through AIP, USA, October 2002, vol. 74, no. 4, p. 1153-1201, by D. Budker et al. Although Expression (2) is associated with linear optical rotation, substantially the same expression may be used even in the case of NMOR.). The signal processing circuit 8 measures the intensity of the magnetic field in the propagation direction of the laser beam from the rotation angle of the polarization plane. The display device 9 displays the intensity of the magnetic field measured by the signal processing circuit 8.

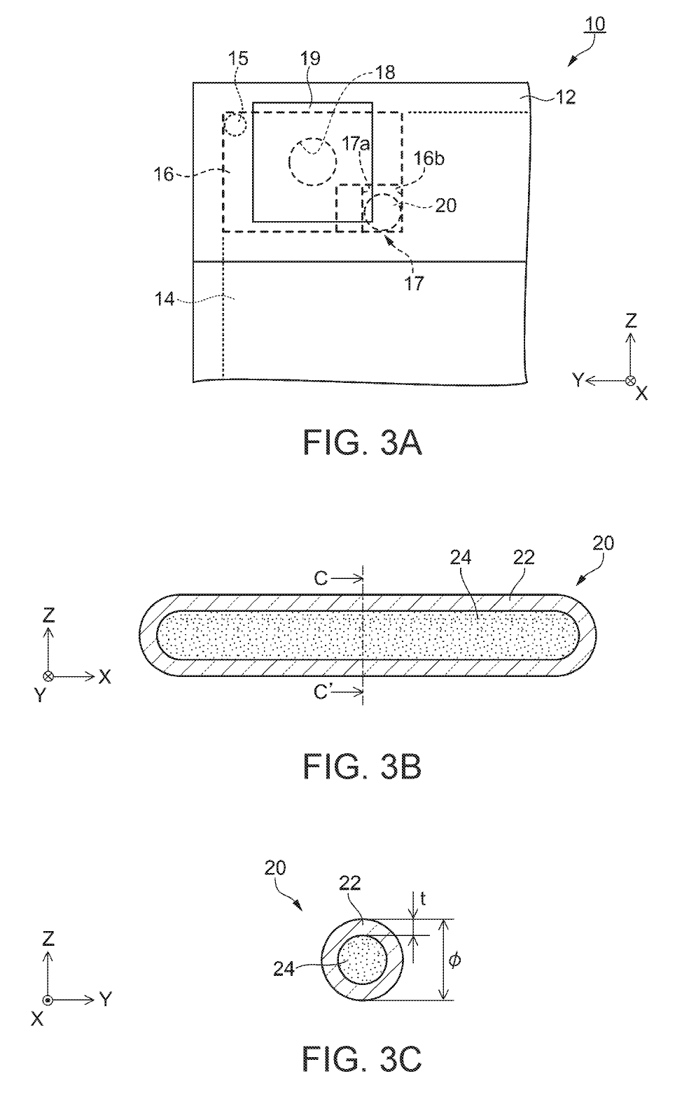

Subsequently, the configurations of the gas cell according to the first embodiment and an ampoule used in the gas cell will be described with reference to FIGS. 2A to 3C.

### Configuration of Gas Cell

FIG. 2A is a sectional side view of the gas cell according to the first embodiment along the longitudinal direction thereof. FIG. 2B is a sectional plan view taken along line A-A′ of FIG. 2A. FIG. 3A is a side view when viewed from a sealing portion of the gas cell according to the first embodiment.

In FIGS. 2A, 2B, and 3A, the height direction of the gas cell 10 is referred to as a Z axis, and the upper side thereof is referred to as a +Z direction. The longitudinal direction of the gas cell 10 which is a direction that intersects the Z axis is referred to as an X axis, and the right side in FIGS. 2A and 2B is referred to as a +X direction. In addition, the width direction of the gas cell 10 which is a direction that intersects the Z axis and the X axis is referred to as a Y axis, and the left side on the plane of FIG. 3A is referred to as a +Y direction.

As illustrated in FIGS. 2A and 2B, the gas cell 10 according to the first embodiment is constituted by a cell portion 12 as a sealing portion 19. The cell portion 12 is a box (cell) having a void therein, and may be formed of, for example, quartz glass. The inner wall of the cell portion 12 may be coated with, for example, paraffin. The thickness of the cell portion 12 is 1 mm to 5 mm, and for example, about 1.5 mm.

The cell portion 12 has, as internal voids, the main chamber 14 as a first chamber and a reservoir 16 as a second chamber. The main chamber 14 and the reservoir 16 are filled with gas resulting from vaporization of an alkali metal (hereinafter, referred to as alkali metal gas) 13. In the main chamber 14 and the reservoir 16, in addition to the alkali metal gas 13, inert gas such as noble gas may also be present.

The main chamber 14 and the reservoir 16 are disposed to be arranged along the X-axis direction which is the longitudinal direction and communicate with each other via a communication hole 15. The communication hole 15 is provided on the upper side (+Z direction side) of the main chamber 14 and the reservoir 16 (see FIG. 2A). On a side (−X direction side) opposite to the main chamber 14 and the communication hole 15 in the longitudinal direction of the reservoir 16, an opening 18 is provided. The opening 18 is provided close to the upper side of the reservoir 16 (see FIG. 2A).

In the reservoir 16, a holding portion 17 is provided along the X-axis direction which is the longitudinal direction. The holding portion 17 is formed as a recessed portion which is recessed from a wall surface 16a of the inner wall of the reservoir 16 on the side on which the opening 18 is provided (−X direction side) toward the −X direction side along the longitudinal direction. A stepped portion is formed between the wall surface 16a and the holding portion 17 (recessed portion) recessed from the wall surface 16a along the X-axis direction, and a surface on the −Y direction side, which forms the stepped portion, becomes an inclined surface 17a inclined with respect to the X-axis direction. The inclined surface 17a (stepped portion) functions as a barrier that defines the holding portion 17 in the reservoir 16. In addition, the depth of the holding portion 17 (recessed portion) in the −X direction, the width thereof in the Y-axis direction, and the inclination angle of the inclined surface 17a with respect to the X-axis direction are appropriately set depending on the external shape of an ampoule 20, which will be described later.

In the reservoir 16, the ampoule 20 is accommodated along the X-axis direction which is the longitudinal direction. The ampoule 20 is disposed such that the tip end portion thereof on the −X direction side is accommodated in the holding portion 17, that is, the tip end portion thereof on the −X direction side is positioned closer to the −Y direction side than the inclined surface 17a and closer to the −X direction side than the wall surface 16a. Accordingly, the ampoule 20 is held in the holding portion 17 in the reservoir 16. A through-hole (opening) 21 is formed in a glass tube 22 of the ampoule 20. The configuration of the ampoule 20 will be described later.

In FIG. 2A, line A-A′ is a line that passes through the center of the opening 18, the reservoir 16, the center of the communication hole 15, and the main chamber 14 along the X-axis direction. In FIG. 2B, line B-B′ is a line that passes through the center of the opening 18, the reservoir 16, the center of the ampoule 20 the center of the communication hole 15, and the main chamber 14 along the X-axis direction. FIG. 2A is a sectional view of a section taken along line B-B′ of FIG. 2B viewed from the −Y direction side, and FIG. 2B is a sectional view taken along line A-A′ of FIG. 2A viewed from the +Z direction side.

FIG. 3A is a side view of the gas cell 10 viewed from the −X direction side in the longitudinal direction. As illustrated in FIG. 3A, the communication hole 15 has, for example, a circular shape. The inner diameter of the communication hole 15 is, for example, about 0.4 mm to 1 mm. The opening 18 also has, for example, a circular shape. The inner diameter of the opening 18 is, for example, about 0.4 mm to 1.5 mm.

The opening 18 is sealed by the sealing portion 19. Accordingly, the cell portion 12 (the main chamber 14 and the reservoir 16) is sealed. The sealing portion 19 has, for example, a rectangular shape, but may also have another shape such as a circular shape. As the material of the sealing portion 19, for example, quartz glass may be used. For example, the sealing portion 19 is fixed to the cell portion 12 via low-melting-point glass frit (not illustrated) disposed in the surrounding area of the opening 18.

When viewed from the sealing portion 19 side, the ampoule 20 is disposed between a wall surface 16b of the inner wall of the reservoir 16 on the −Y direction side and the inclined surface (stepped portion) 17a of the holding portion 17. In addition, it is preferable that the holding portion 17 is disposed at a position distant from the opening 18 and the communication hole 15. In this embodiment, as illustrated in FIG. 3A, the holding portion 17 is disposed on the −Y direction side and the −Z direction side distant from the opening 18 and the communication hole 15.

### Configuration of Ampoule

FIG. 3B is a sectional view of the ampoule according to the first embodiment along the longitudinal direction. FIG. 3C is a schematic cross-sectional view taken along line C-C′ of FIG. 3B. As illustrated in FIG. 3B, the ampoule 20 as a solid containing the alkali metal according to the first embodiment has its longitudinal direction. FIG. 3B illustrates an X-Z section of the ampoule 20 when the ampoule 20 is disposed so that the longitudinal direction thereof follows the X-axis direction. The ampoule 20 is formed as a hollow glass tube 22. The glass tube 22 is, for example, formed of borosilicate glass.

The glass tube 22 extends along one direction (the X-axis direction in FIG. 3B), and both end portions thereof are welded. Accordingly, the glass tube 22 having the hollow inside is sealed. In addition, the shape of both end portions of the glass tube 22 is not limited to a round shape illustrated in FIG. 3B, and may also be a shape close to a flat surface, or a partially sharp shape. The hollow inside of the glass tube 22 is filled with the alkali metal solid (a granular or powdery material having alkali metal atoms) 24. As the alkali metal solid 24, as described above, rubidium, potassium, or sodium may also be used other than cesium.

FIG. 3B illustrates a state in which the ampoule 20 (the glass tube 22) is sealed. In a stage in which the ampoule 20 is manufactured, the glass tube 22 is in a sealed state. However, in a stage in which the gas cell 10 is completed, the through-hole 21 (see FIG. 2A) is formed in the glass tube 22 and the seal is broken. Accordingly, the alkali metal solid 24 in the ampoule 20 is vaporized and flows into the gas cell 10 such that the voids of the cell portion 12 are filled with the alkali metal gas 13 (see FIG. 2A). In addition, in order to cause the alkali metal solid 24 to be vaporized and easily leak from the ampoule 20, for example, a gap of about 1.5 mm in the +Z direction is provided between the upper surface of the ampoule 20 and the inner surface of the cell portion 12 (see FIG. 2A).

FIG. 3C illustrates a Y-Z cross-section of the ampoule 20 in a direction intersecting the longitudinal direction. As illustrated in FIG. 3C, the Y-Z cross-sectional shape of the glass tube 22 is, for example, a substantially circular shape, but may also be another shape. The outer diameter φ of the glass tube 22 is 0.2 mm≦φ≦1.2 mm. The thickness t of the glass tube 22 is 0.1 mm≦t≦0.5 mm, and is preferably about 20% of the outer diameter φ thereof. When the thickness t of the glass tube 22 is smaller than 0.1 mm, the glass tube 22 is easily broken. When the thickness t of the glass tube 22 is greater than 0.5 mm, it is difficult to perform a process of forming the through-hole 21 in the glass tube 22 (details will be described later).

### Manufacturing Method of Gas Cell

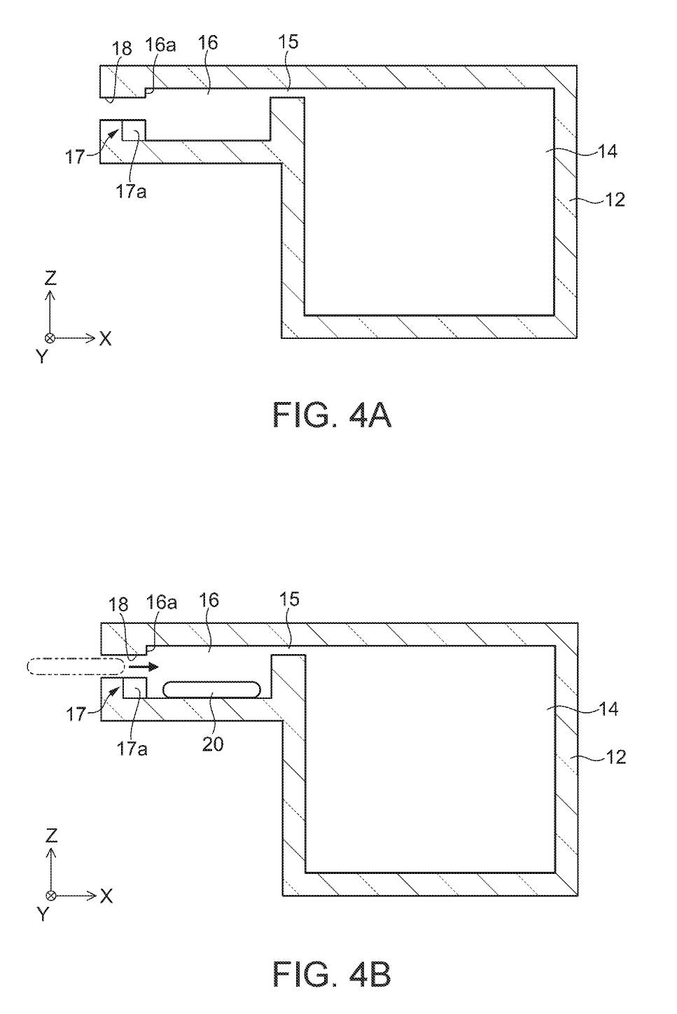

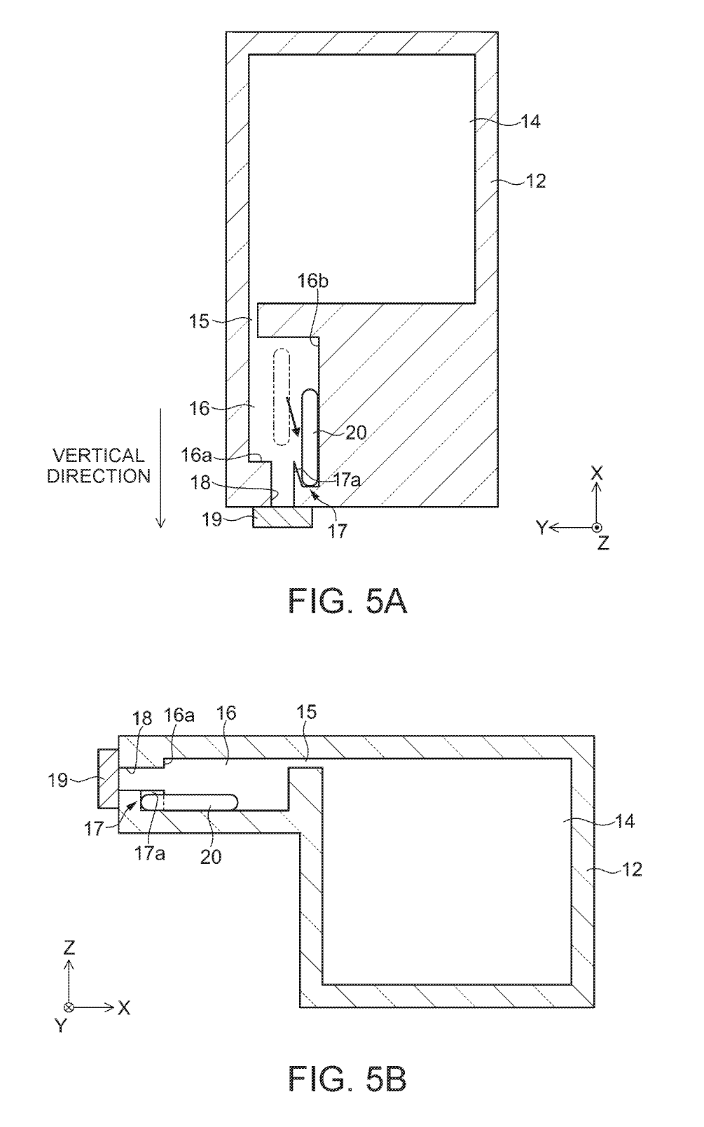

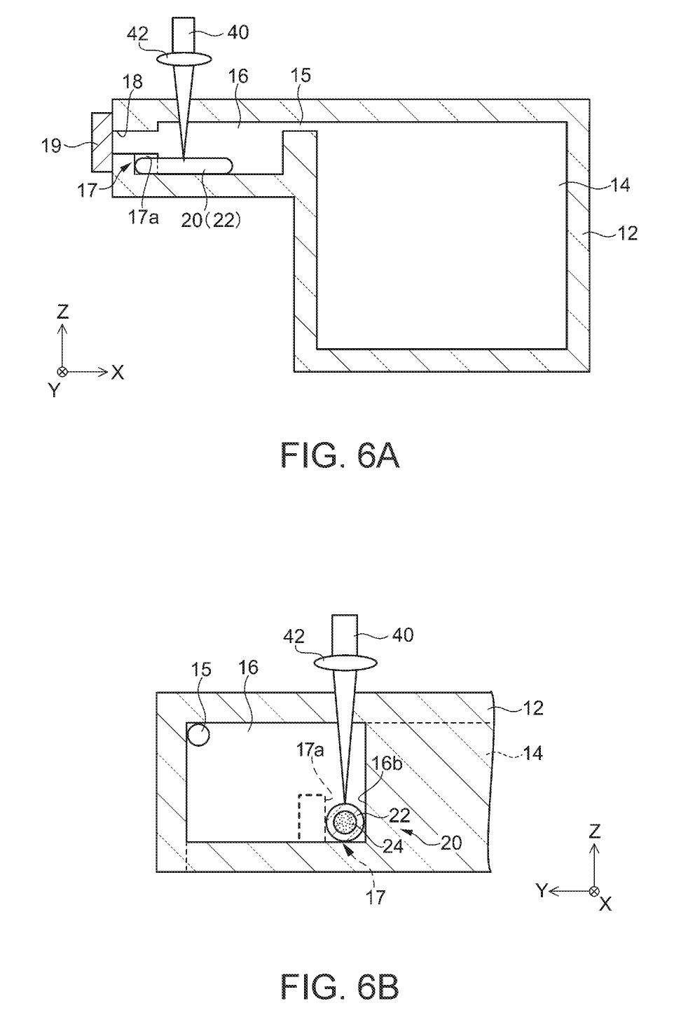

Next, a manufacturing method of the gas cell according to the first embodiment will be described with reference to FIGS. 4A to 6B. FIGS. 4A to 6B are views illustrating the manufacturing method of the gas cell according to the first embodiment. FIGS. 4A, 4B, 5B, and 6A are sectional side views corresponding to FIG. 2A, FIG. 5A is a sectional plan view corresponding to FIG. 2B, and FIG. 6B is a sectional view of FIG. 6A at a laser light irradiation position. The manufacturing method of the gas cell according to this embodiment includes a disposing process, a sealing process, and an irradiation process.

First, the cell portion 12 illustrated in FIG. 4A is prepared. Although not illustrated, for example, by cutting a glass plate made of quartz glass, glass plate members corresponding to the wall surfaces constituting the cell portion 12 are prepared. In addition, the glass plate members are assembled, and the glass plate members are joined together by an adhesive or by welding such that the cell portion 12 having the main chamber 14 and the reservoir 16 as illustrated in FIG. 4A is obtained. In this stage, the opening 18 of the cell portion 12 is open. In addition, the holding portion 17 in the reservoir 16 may be configured by processing the glass plate members and forming the recessed portion and the inclined surface 17a.

Subsequently, as illustrated in FIG. 4B, the ampoule 20 is disposed in the reservoir 16 of the cell portion 12 (disposing process). As indicated by arrow in FIG. 4B, the ampoule 20 is inserted into the reservoir 16 along the longitudinal direction (X-axis direction) through the opening 18 provided in the reservoir 16 of the cell portion 12. The ampoule 20 is inserted into the reservoir 16 so that the extension direction thereof follows the longitudinal direction (X-axis direction) of the reservoir 16.

After inserting the ampoule 20 into the reservoir 16, the ampoule 20 is disposed in the holding portion 17. As indicated by arrow in FIG. 5A, by moving the ampoule 20 toward the −X direction side while the ampoule 20 is allowed to follow the wall surface 16b of the inner wall on the −Y direction side of the reservoir 16, the ampoule 20 is accommodated and held in the holding portion 17. For example, when the reservoir 16 is inclined in the state illustrated in FIG. 4B so as to cause the −Y direction side of the reservoir 16 (the cell portion 12) to be lower than the +Y direction side, the ampoule can approach the wall surface 16b. In addition, as illustrated in FIG. 5A, by changing the posture of the cell portion 12 so as to cause the opening 18 to be on the lower side in a vertical direction, the ampoule 20 can be moved toward the holding portion 17 side (−X direction side).

At this time, the tip end of the ampoule 20 is guided by the inclined surface 17a, and thus the ampoule 20 can be easily disposed in the holding portion 17. In addition, in the state in which the ampoule 20 is disposed in the holding portion 17, the inclined surface 17a functions as the barrier that defines the holding portion 17 in the reservoir 16. Therefore, during handling through the disposing process to the sealing process, the ampoule 20 can be prevented from coming out from the reservoir 16 through the opening 18.

In stages to the disposing process, as illustrated in FIG. 3B, the ampoule 20 is in a state of being filled with the alkali metal solid 24 in the hollow glass tube 22 and sealed. The ampoule 20 is formed by filling the hollow of the tubular glass tube 22 with the alkali metal solid 24 in an atmosphere at a low pressure close to vacuum (ideally, in a vacuum) and welding and sealing both end portions of the glass tube 22. The alkali metal such as cesium used as the alkali metal solid 24 has high reactivity and cannot be treated in the air. Therefore, the alkali metal is thus accommodated in the cell portion 12 in a state of being sealed in the ampoule 20 in the environment at a low pressure.

Subsequently, as illustrated in FIG. 5A, the opening 18 of the reservoir 16 is sealed by the sealing portion 19 (sealing process). In the sealing process, the inside of the cell portion 12 is sufficiently evacuated, and in a state where an excessively small amount of impurities is present therein, the cell portion 12 (the main chamber 14, the communication hole 15, and the reservoir 16) is sealed. For example, in the environment at a low pressure closer to vacuum (ideally, in a vacuum), low-melting-point glass frit (not illustrated) is disposed around the opening 18 of at least one of the cell portion 12 and the sealing portion 19, and the cell portion 12 and the sealing portion 19 are fixed and sealed with each other. Accordingly, the cell portion 12 is sealed.

When the cell portion 12 and the sealing portion 19 are fixed to each other, as illustrated in FIG. 5A, it is preferable that the cell portion 12 is disposed on the sealing portion 19 while the longitudinal direction follows the vertical direction and the opening 18 is disposed on the lower side in the vertical direction. With this disposition, sealing can be efficiently performed by applying a load onto the cell portion 12 positioned on the upper side from the sealing portion 19 side positioned on the lower side in the vertical direction while heating the low-melting-point glass frit and causing the cell portion 12 and the sealing portion 19 to be come into close contact with each other.

Here, in a case where the holding portion 17 is not disposed in the reservoir 16, when the cell portion 12 is disposed in the sealing process so as to cause the opening 18 to be on the lower side in the vertical direction, since the ampoule 20 is disposed so as to cause the longitudinal direction to follow the vertical direction, there is concern that the ampoule 20 may come out from the reservoir 16 through the opening 18. In this embodiment, since the ampoule 20 is held in the holding portion 17, even when the cell portion 12 is disposed in the sealing process so as to cause the opening 18 to be on the lower side, the ampoule 20 can be prevented from coming out from the reservoir 16 through the opening 18. FIG. 5B illustrates the ampoule 20 held in the holding portion 17 in the reservoir 16 and the cell portion 12 with the opening 18 sealed by the sealing portion 19, after the sealing process.

Subsequently, as illustrated in FIGS. 6A and 6B, pulsed laser light 40 is concentrated on a condensing lens 42 to irradiate the glass tube 22 of the ampoule 20 through the cell portion 12 (irradiation process). The pulsed laser light 40 is emitted to connect focal points on the upper surface of the ampoule 20 (glass tube 22). Accordingly, the through-hole 21 (see FIG. 2A) is formed in the glass tube 22 such that the alkali metal solid 24 in the ampoule 20 is vaporized to flow through the voids of the gas cell 10. Since laser light has excellent directivity and convergence, the through-hole 21 can be easily formed in the glass tube 22 by emitting the pulsed laser light 40 thereto.

In the irradiation process, the through-hole 21 needs to be formed in the glass tube 22 of the ampoule 20 without damage to the cell portion 12. In a case where the cell portion 12 is formed of quartz glass and the glass tube 22 is formed of borosilicate glass, for example, pulsed laser light 40 with a wavelength in the ultraviolet region is used. Light with a wavelength in the ultraviolet region is transmitted through the quartz glass but is slightly absorbed by borosilicate glass. Accordingly, the through-hole 21 can be formed by selectively processing the glass tube 22 of the ampoule 20 without damage to the cell portion 12.

The energy of the pulsed laser light 40 is set to, for example, 20 μJ/pulse to 200 μJ/pulse. The pulse width of the pulsed laser light 40 is, for example, 10 nanoseconds to 50 nanoseconds, and is preferably about 30 nanoseconds. The repetition frequency of the pulsed laser light 40 is set to, for example, about 50 kHz, and the irradiation time of the pulsed laser light 40 is set to, for example, about 100 milliseconds.

In addition, in order to reliably form the through-hole 21 in the glass tube 22 of the ampoule 20 in the irradiation process, it is preferable that the position of irradiation of the ampoule 20 with the pulsed laser light 40 is set so as to cause the focal point of the pulsed laser light 40 to be positioned at the center portion of the ampoule 20 in the width direction (Y-axis direction). When the focal point of the pulsed laser light 40 deviates from the center portion of the ampoule 20 in the width direction, there may be cases where processing performed in the depth direction does not proceed and the glass tube 22 cannot be penetrated.

As the through-hole 21 is formed in the ampoule 20, the seal of the ampoule 20 in the reservoir 16 is broken, and the alkali metal solid 24 is vaporized into the alkali metal gas 13 and flows out from the inside of the ampoule 20. The alkali metal gas 13 flowing toward the inside of the reservoir 16 passes through the communication hole 15 and flows into the main chamber 14 of the cell portion 12, and is diffused. As a result, as illustrated in FIG. 2A, the voids of the cell portion 12 are filled with the alkali metal gas 13.

However, in a case where the holding portion 17 is not provided in the reservoir 16, the ampoule 20 is not held in a stable state, and the position of the ampoule 20 in the reservoir 16 varies by the individual. Otherwise, the ampoule 20 may be moved due to a slight inclination or impact during handling of the cell portion 12 and may deviate from the position of irradiation with the pulsed laser light 40. In addition, when the ampoule 20 is not held in a stable state, the ampoule 20 may be moved due to an impact caused by the irradiation with the pulsed laser light 40 and may deviate from its position. In this case, the through-hole 21 cannot be formed in the glass tube 22 in the irradiation process, and a reduction in manufacturing yield in the processes for manufacturing the gas cell 10 or an increase in the number of manufacturing processes due to re-processing may be incurred.

In this embodiment, as illustrated in FIGS. 6A and 6B, since the ampoule 20 is held in the holding portion 17 in the reservoir 16, deviation of the position of the ampoule 20 in the reservoir 16 or movement of the ampoule 20 during handling can be prevented. Therefore, deviation of the ampoule 20 from the position of irradiation with the pulsed laser light 40 can be prevented. In addition, in the irradiation process, movement of the ampoule 20 due to an impact caused by the irradiation with the pulsed laser light 40 is prevented. Accordingly, the alkali metal gas 13 can be generated by stably and reliably forming the through-hole 21 in the ampoule 20. Therefore, a reduction in the manufacturing yield of the gas cell 10 or an increase in the number of manufacturing processes can be prevented, and thus productivity can be improved.

In addition, in the irradiation process, the alkali metal solid 24 may be vaporized and flow out from the ampoule 20. Therefore, the ampoule 20 is not limited to the formation of the through-hole 21. For example, the ampoule 20 may be divided by initiating cracking in the glass tube 22, or the glass tube 22 may be broken. However, in this case, when fragments of the glass tube 22 or the alkali metal solid 24 discharged from the ampoule 20 passes through the communication hole 15 and infiltrates into the main chamber 14, a reduction in the measurement accuracy of the magnetism measuring device 100 may be incurred.

In this embodiment, since the holding portion 17 is disposed on the −Y direction side and the −Z direction side distant from the communication hole 15, infiltration of the fragments of the glass tube 22 or the alkali metal solid 24 into the main chamber 14 can be prevented. Accordingly, the magnetism measuring device 100 having excellent measurement accuracy can be manufactured and provided.

A manufacturing method of the magnetism measuring device 100 according to this embodiment includes the manufacturing method of the gas cell 10 described above. Regarding processes for manufacturing the magnetism measuring device 100 according to this embodiment, well-known methods may be used as processes other than the processes for manufacturing the gas cell 10. Therefore, description thereof will be omitted.

### Second Embodiment

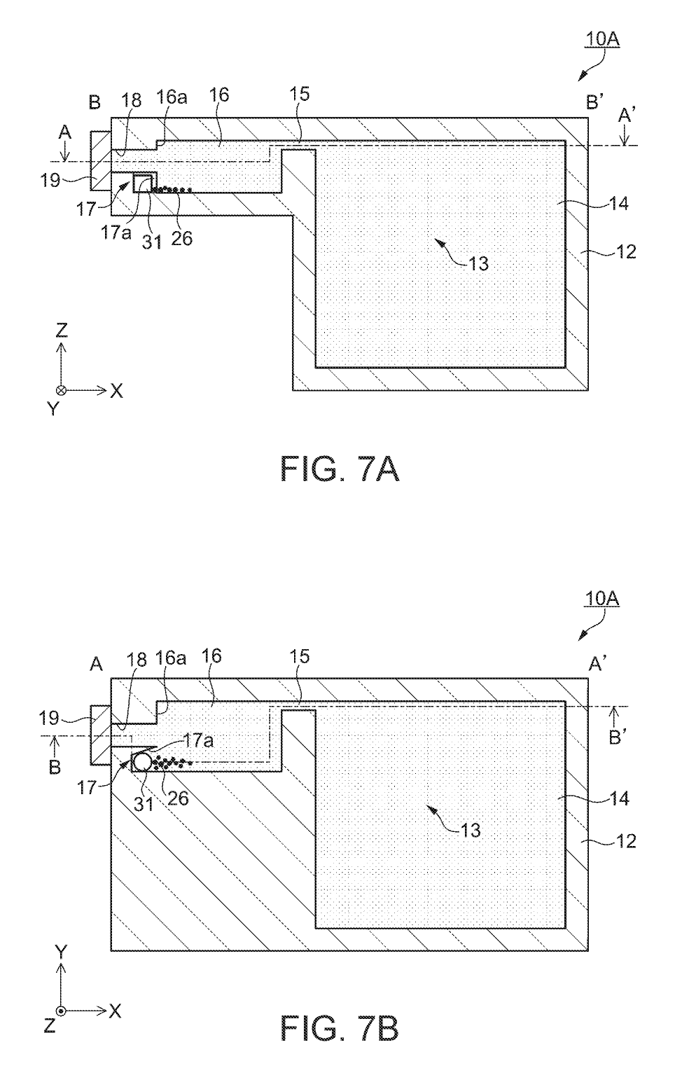

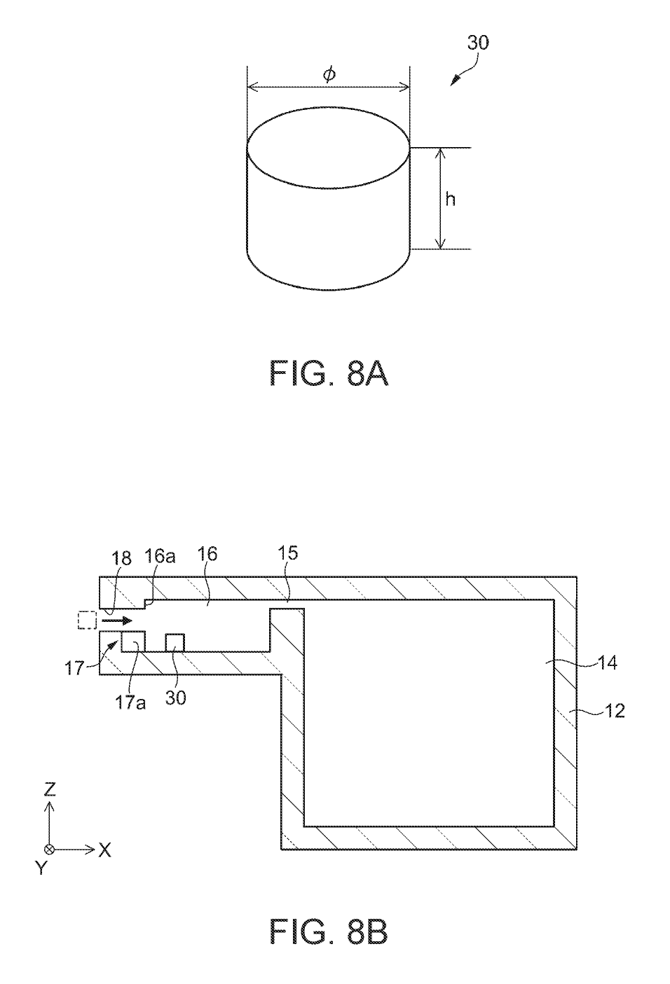

A second embodiment is different from the first embodiment in that a solid containing the alkali metal is not the ampoule but a pill. However, the configuration of the cell portion is substantially the same. The configurations of a gas cell according to the second ampoule and a pill used in the gas cell will be described with reference to FIGS. 7A to 8A. In addition, like elements which are common to those of the first embodiment are denoted by like reference numerals, and description thereof will be omitted.

### Configuration of Pill

First, the configuration of the pill as the solid containing the alkali metal according to the second embodiment will be described. FIG. 8A is a perspective view of the pill according to the second embodiment. As illustrated in FIG. 8A, a pill 30 according to the second embodiment is, for example, substantially cylindrical. The diameter φ of the cylinder of the pill 30 is, for example, about 1 mm, and the height t of the cylinder of the pill 30 is, for example, about 1 mm. The external shape of the pill 30 is not limited to the substantially cylindrical shape and may be another shape such as a rectangular parallelepiped or spherical shape.

The pill 30 contains an alkali metal compound and an adsorbent. When the pill 30 is irradiated with laser light in an irradiation process, which will be described later, the alkali metal compound is activated and the alkali metal is generated. Impurities or impure gases emitted at this time are adsorbed onto the adsorbent. In a case where cesium is used as the alkali metal, a cesium compound such as cesium molybdate or cesium chloride may be used as the alkali metal compound. As the adsorbent, for example, zirconium powder or aluminum may be used.

### Configuration of Gas Cell

FIG. 7A is a sectional side view of the gas cell according to the second embodiment along the longitudinal direction. FIG. 7B is a sectional plan view taken along line A-A′ of FIG. 7A. FIG. 7A is a sectional view of a section taken along line B-B′ of FIG. 7B viewed from the −Y direction side, and FIG. 7B is a sectional view of a section taken along line A-A′ of FIG. 7A viewed from the +Z direction side.

As illustrated in FIGS. 7A and 7B, like the gas cell 10 according to the first embodiment, a gas cell 10A according to the second embodiment includes the cell portion 12 having the main chamber 14 and the reservoir 16 which communicate with each other via the communication hole 15, and the sealing portion 19. In the reservoir 16, the holding portion 17 formed as a recessed portion which is recessed from the wall surface 16a of the inner wall toward the −X direction side along the longitudinal direction is provided. In addition, the depth of the holding portion 17 (recessed portion) in the −X direction, the width thereof in the Y-axis direction, and the inclination angle of the inclined surface 17a with respect to the X-axis direction are appropriately set depending on the external shape of the pill 30.

In a state in which the gas cell 10A illustrated in FIGS. 7A and 7B is completed, an alkali metal 26 (for example, cesium) is generated from the alkali metal compound in the pill 30 in the reservoir 16, and the main chamber 14 and the reservoir 16 are filled with an alkali metal gas 13 into which the alkali metal 26 is vaporized. An adsorbent 31 onto which impure gases are adsorbed, impurities, and the like may remain in the reservoir 16.

### Manufacturing Method of Gas Cell

Next, a manufacturing method of the gas cell according to the second embodiment will be described with reference to FIGS. 8B to 10B. FIGS. 8B to 10B are views illustrating the manufacturing method of the gas cell according to the second embodiment. The manufacturing method of the gas cell according to the second embodiment is different from the manufacturing method of the gas cell according to the first embodiment in that the pill 30 is disposed in the reservoir 16 in the disposing process and continuous oscillating laser light is emitted in the irradiation process. However, the other configurations are substantially the same. Description of parts of the manufacturing method common to those of the first embodiment will be omitted.

As illustrated in FIG. 8B, the cell portion 12 is prepared, and the pill 30 is disposed in the reservoir 16 of the cell portion 12 (disposing process). As indicated by arrow in FIG. 8B, the pill 30 is inserted into the reservoir 16 along the longitudinal direction (X-axis direction) through the opening 18 provided in the reservoir 16 of the cell portion 12.

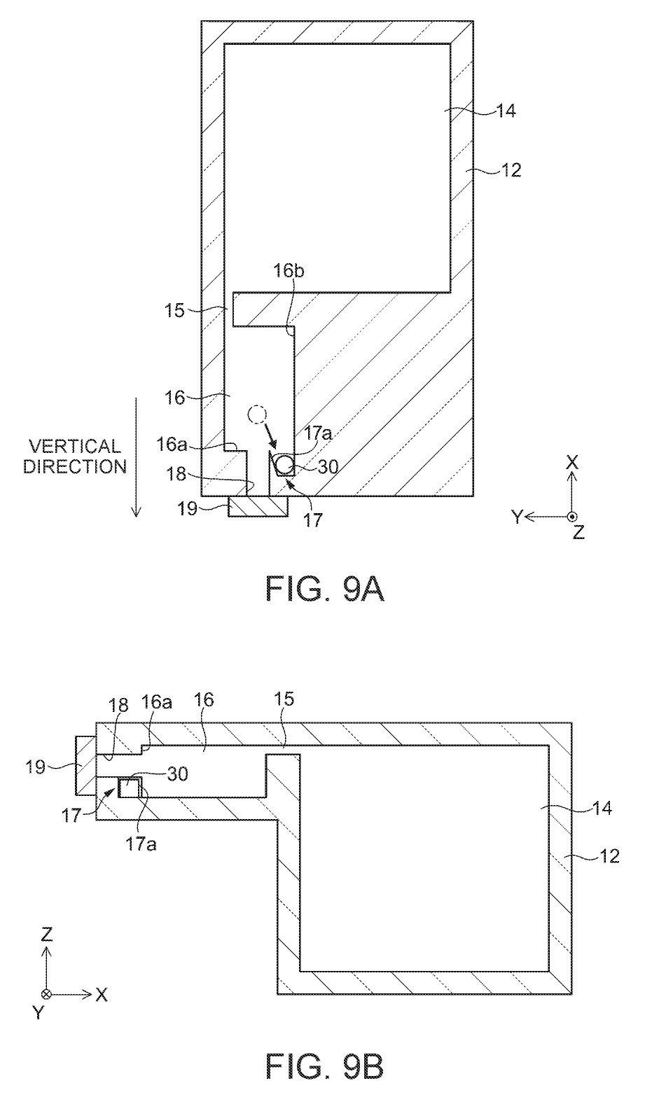

After inserting the pill 30 into the reservoir 16, the pill 30 is disposed in the holding portion 17. As indicated by arrow in FIG. 9A, as in the case of the ampoule 20 of the first embodiment, by moving the pill 30 toward the −X direction side while the pill 30 is allowed to follow the wall surface 16b (see FIG. 9A) of the inner wall on the −Y direction side of the reservoir 16, the pill 30 is accommodated and held in the holding portion 17.

At this time, the pill 30 is guided by the inclined surface 17a, and thus the pill 30 can be easily disposed in the holding portion 17. In addition, in the state in which the pill 30 is disposed in the holding portion 17, the inclined surface 17a functions as the barrier that defines the holding portion 17 in the reservoir 16. Therefore, during handling through the disposing process to the sealing process, the pill 30 can be prevented from coming out from the reservoir 16 through the opening 18.

Subsequently, as illustrated in FIG. 9A, as in the same method as the first embodiment, the opening 18 of the reservoir 16 is sealed by the sealing portion 19 (sealing process). In the sealing process, since the pill 30 is held in the holding portion 17, even when the cell portion 12 is disposed so as to cause the opening 18 to be on the lower side, the pill 30 can be prevented from coming out from the reservoir 16 through the opening 18. FIG. 9B illustrates the pill 30 held in the holding portion 17 in the reservoir 16 and the cell portion 12 with the opening 18 sealed by the sealing portion 19, after the sealing process.

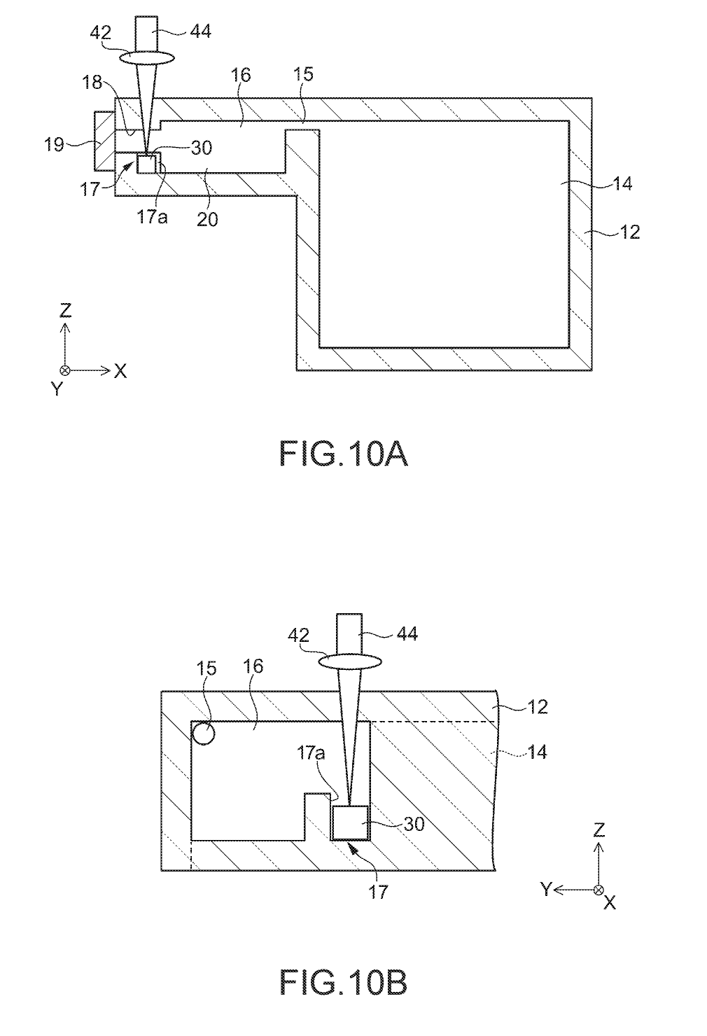

Subsequently, as illustrated in FIGS. 10A and 10B, continuous oscillating laser light 44 is concentrated on the condensing lens 42 to irradiate the pill 30 through the cell portion 12 (irradiation process). The continuous oscillating laser light 44 is emitted to connect focal points at substantially the center portion on the upper surface of the pill 30.

As the continuous oscillating laser light 44, for example, laser diode (LD) laser which continuously oscillates at a wavelength of about 680 nm to 1200 nm may be used. The wavelength of the continuous oscillating laser light 44 is preferably about 800 nm. The output of the continuous oscillating laser light 44 is, for example, about 1 W to 10 W, and is preferably about 2 W to 5 W. The irradiation time of the continuous oscillating laser light 44 is for example, about 10 seconds to 5 minutes, and is preferably 30 seconds to 90 seconds.

By emitting the continuous oscillating laser light 44, the pill 30 is heated, the alkali metal compound contained in the pill 30 is activated, and the alkali metal 26 is generated. In addition, the alkali metal 26 is vaporized into the alkali metal gas 13, flows toward the inside of the reservoir 16, flows into the main chamber 14 of the cell portion 12 through the communication hole 15, and is diffused. As a result, as illustrated in FIGS. 7A and 7B, the voids of the cell portion 12 are filled with the alkali metal gas 13. Impurities or impure gases emitted from the alkali metal compound are adsorbed onto the adsorbent 31 (see FIG. 7A).

In the gas cell 10A according to the second embodiment, the pill 30 needs to be heated without damage to the cell portion 12. In the irradiation process according to the second embodiment, the pill 30 is locally heated by being irradiated with the continuous oscillating laser light 44. Therefore, compared to a case where the entire reservoir 16 (the cell portion 12) with the pill 30 accommodated therein is heated, an effect of heat on the members constituting the cell portion 12 can be suppressed.

In order to locally heat the pill 30, it is preferable that the position of irradiation of the pill 30 with the continuous oscillating laser light 44 is set so as to cause the focal point of the continuous oscillating laser light 44 to be positioned at the center portion of the upper surface of the pill 30. When the focal point of the continuous oscillating laser light 44 deviates from the pill 30, the pill 30 is insufficiently heated, and generation of the alkali metal does not proceed. AS a result, a reduction in the manufacturing yield of the gas cell 10A or an increase in the number of manufacturing processes due to re-processing may be incurred.

In this embodiment, as illustrated in FIGS. 10A and 10B, since the pill 30 is held in the holding portion 17 in the reservoir 16, deviation of the position of the pill 30 in the reservoir 16 or movement of the pill 30 during handling can be prevented. Therefore, deviation of the pill 30 from the position of irradiation with the continuous oscillating laser light 44 can be prevented. In addition, in the irradiation process, movement of the pill 30 due to an impact caused by the irradiation with the continuous oscillating laser light 44 is prevented. Accordingly, the alkali metal gas 13 can be generated by stably and reliably irradiating and heating the pill 30 with the continuous oscillating laser light 44. Therefore, a reduction in the manufacturing yield of the gas cell 10A or an increase in the number of manufacturing processes can be prevented, and thus productivity can be improved.

The above-described embodiments describe only aspects of the invention, and arbitrary modifications and applications can be made without departing from the scope of the invention. As modification examples, for example, the following may be considered.

### Modification Example 1

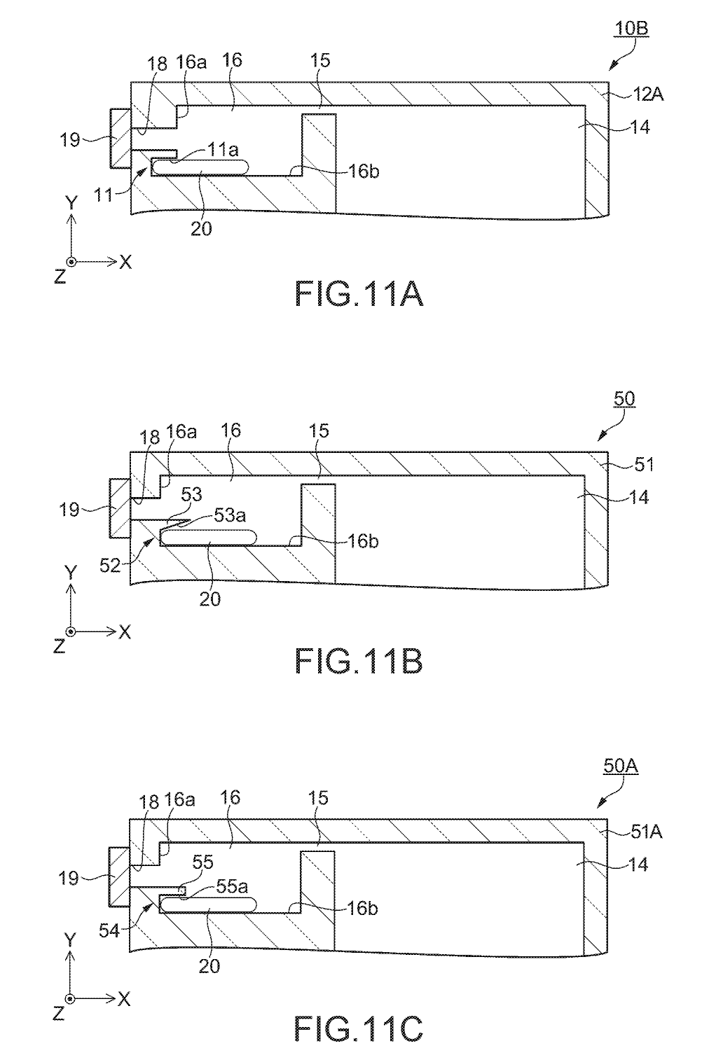

The magnetism measuring device and the gas cells of the above-described embodiments are configured so that the holding portion provided in the reservoir is formed as the recessed portion recessed in the longitudinal direction and the inclined surface is provided. However, the invention is not limited to this configuration. The holding portion may have a configuration other than that in the above-described embodiments. FIGS. 11A to 11C are partial sectional plan views illustrating configuration examples of the gas cell according to Modification Example 1. FIGS. 11A to 11C correspond to the sectional plan view illustrated in FIG. 2B.

As illustrated in FIG. 11A, a cell portion 12A of a gas cell 10B includes a holding portion 11 formed as a recessed portion which is recessed from the wall surface 16a of the reservoir 16 toward the −X direction side along the longitudinal direction. A surface 11a of the holding portion 11 along the longitudinal direction of the ampoule 20 is not an inclined surface but a surface substantially parallel to the wall surface 16b of the inner wall of the reservoir 16 on the −Y direction side. In this configuration, in the state in which the ampoule 20 is disposed in the holding portion 11, the surface 11a which is a surface substantially parallel to the wall surface 16b functions as a barrier that defines the holding portion 11 in the reservoir 16. Therefore, during handling through the disposing process to the sealing process, discharge of the ampoule 20 from the reservoir 16 through the opening 18 or movement of the ampoule 20 due to an impact caused by the irradiation with the pulsed laser light 40 in the irradiation process can be more reliably prevented.

As illustrated in FIG. 11B, a cell portion 51 of a gas cell 50 includes a holding portion 52 formed as a protruding portion 53 (defined by the protruding portion 53) which extends from the wall surface 16a of the reservoir 16 toward the +X direction side along the longitudinal direction. A surface of the protruding portion 53 on the −Y direction side becomes an inclined surface 53a inclined with respect to the X-axis direction. In this configuration, the tip end of the ampoule 20 is guided by the inclined surface 53a in the disposing process, and thus the ampoule 20 can be easily disposed in the holding portion 52. In addition, in the state in which the ampoule 20 is disposed in the holding portion 52, the inclined surface 53a (the protruding portion 53) functions as a barrier that defines the holding portion 52 in the reservoir 16. Therefore, during handling through the disposing process to the sealing process, discharge of the ampoule 20 from the reservoir 16 through the opening 18 or movement of the ampoule 20 due to an impact caused by the irradiation with the pulsed laser light 40 in the irradiation process can be more reliably prevented.

As illustrated in FIG. 11C, a cell portion 51A of a gas cell 50A includes a holding portion 54 formed as a protruding portion 55 (defined by the protruding portion 55) which extends from the wall surface 16a of the reservoir 16 toward the +X direction side along the longitudinal direction. A surface 55a in the holding portion 54 along the longitudinal direction of the ampoule 20 is not an inclined surface but a surface substantially parallel to the wall surface 16b of the inner wall of the reservoir 16 on the −Y direction side. In this configuration, in the state in which the ampoule 20 is disposed in the holding portion 54, the surface 55a (the protruding portion 55) which is a surface substantially parallel to the wall surface 16b functions as a barrier that defines the holding portion 54 in the reservoir 16. Therefore, during handling through the disposing process to the sealing process, discharge of the ampoule 20 from the reservoir 16 through the opening 18 or movement of the ampoule 20 due to an impact caused by the irradiation with the pulsed laser light 40 in the irradiation process can be more reliably prevented.

In the description of the gas cells 10B, 50, and 50A according to Modification Example 1 described above, the ampoule 20 of the first embodiment is used as the solid containing the alkali metal. However, the configurations of the gas cells 10B, 50, and 50A according to Modification Example 1 can also be applied to a case of using the pill 30 of the second embodiment.

### Modification Example 2

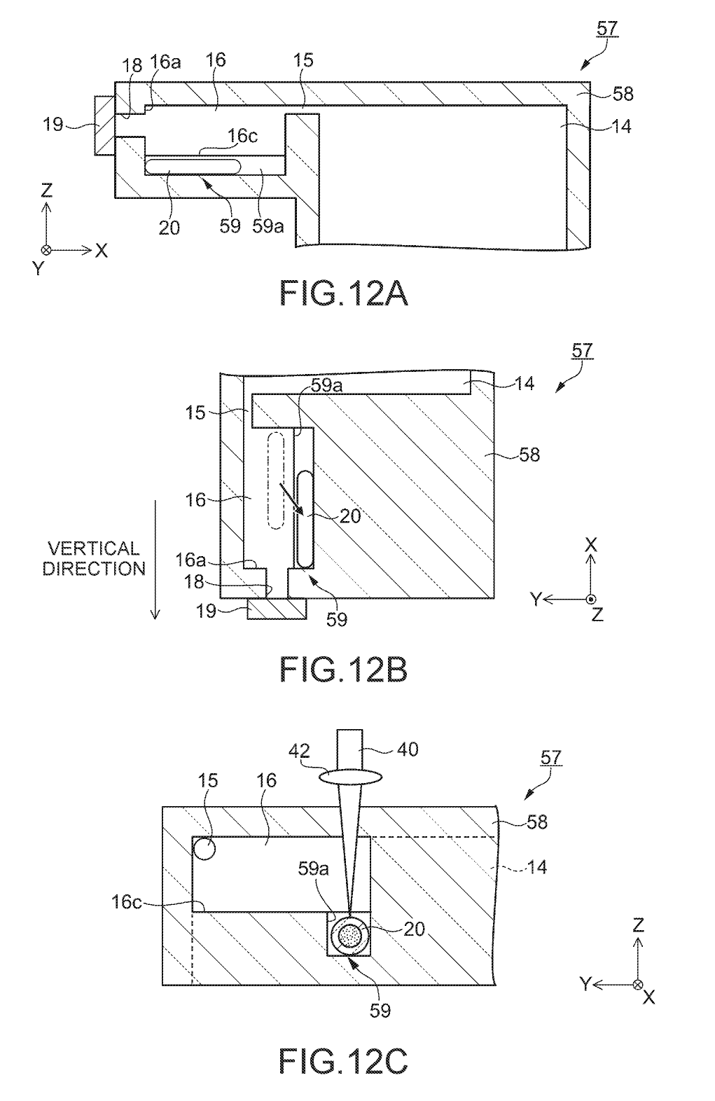

The magnetism measuring device and the gas cells of the above-described embodiments and modification example are configured so that the holding portion is formed as the recessed portion recessed along the longitudinal direction or the protruding portion extending along the longitudinal direction. However, the invention is not limited to this configuration. The holding portion may have a configuration other than that in the above-described embodiments and the modification example. FIGS. 12A to 12C are sectional views illustrating configuration examples of the gas cell according to Modification Example 2. FIG. 12A is a partial sectional side view corresponding to the sectional side view illustrated in FIG. 2A, FIG. 12B is a partial sectional plan view corresponding to the sectional plan view illustrated in FIG. 5A, and FIG. 12C corresponds to a sectional view at a laser light irradiation position illustrated in FIG. 6B.

As illustrated in FIGS. 12A and 12B, a cell portion 58 of a gas cell 57 according to Modification Example 2 includes a holding portion 59 provided along the longitudinal direction in the reservoir 16. As illustrated in FIG. 12C, the holding portion 59 is formed as a recessed portion which is recessed from a bottom surface 16c (a surface on the −Z direction side) of the reservoir 16 toward the −Z direction side. A stepped portion is formed between the bottom surface 16c and the holding portion 59 (recessed portion) recessed from the bottom surface 16c along the X-axis direction, and a surface 59a on the −Y direction side, which forms the stepped portion, functions as a barrier that defines the holding portion 59 in the reservoir 16. In this configuration, when the reservoir 16 is inclined in the disposing process so as to cause the −Y direction side of the reservoir 16 (the cell portion 58) to be lower than the +Y direction side, the ampoule 20 can be accommodated in the holding portion 59 (recessed portion). Therefore, in the irradiation process, movement of the ampoule 20 due to an impact caused by the irradiation with the pulsed laser light 40 can be prevented.

In the description of the gas cell 57 according to Modification Example 2 described above, the ampoule 20 of the first embodiment is used as the solid containing the alkali metal. However, the configuration of the gas cell 57 according to Modification Example 2 can also be applied to a case of using the pill 30 of the second embodiment.

### Modification Example 3

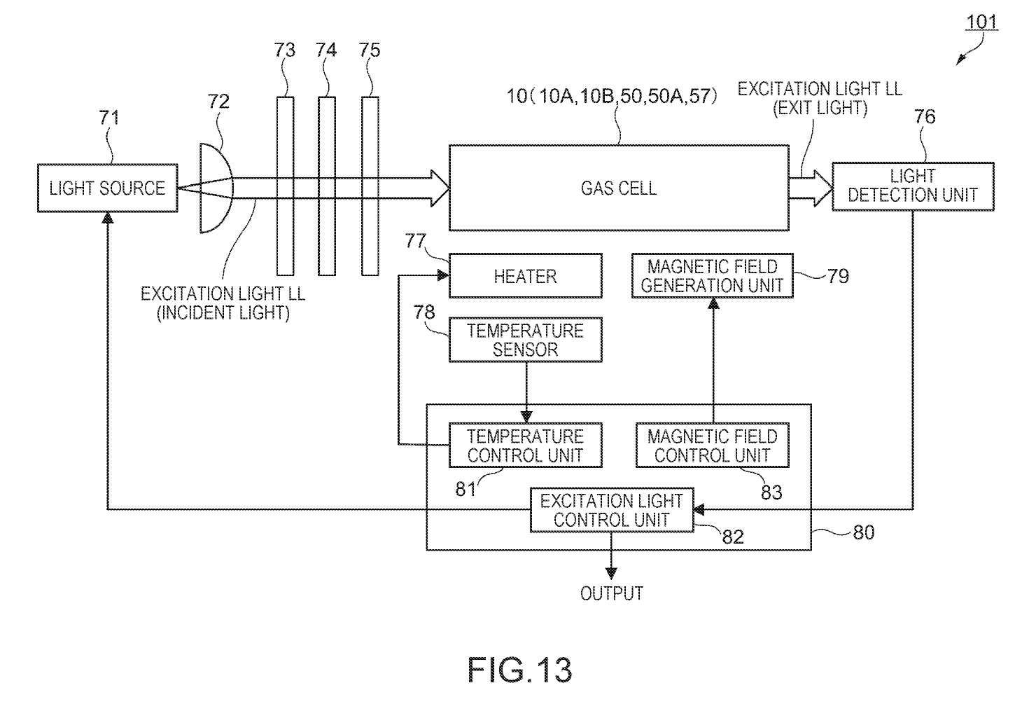

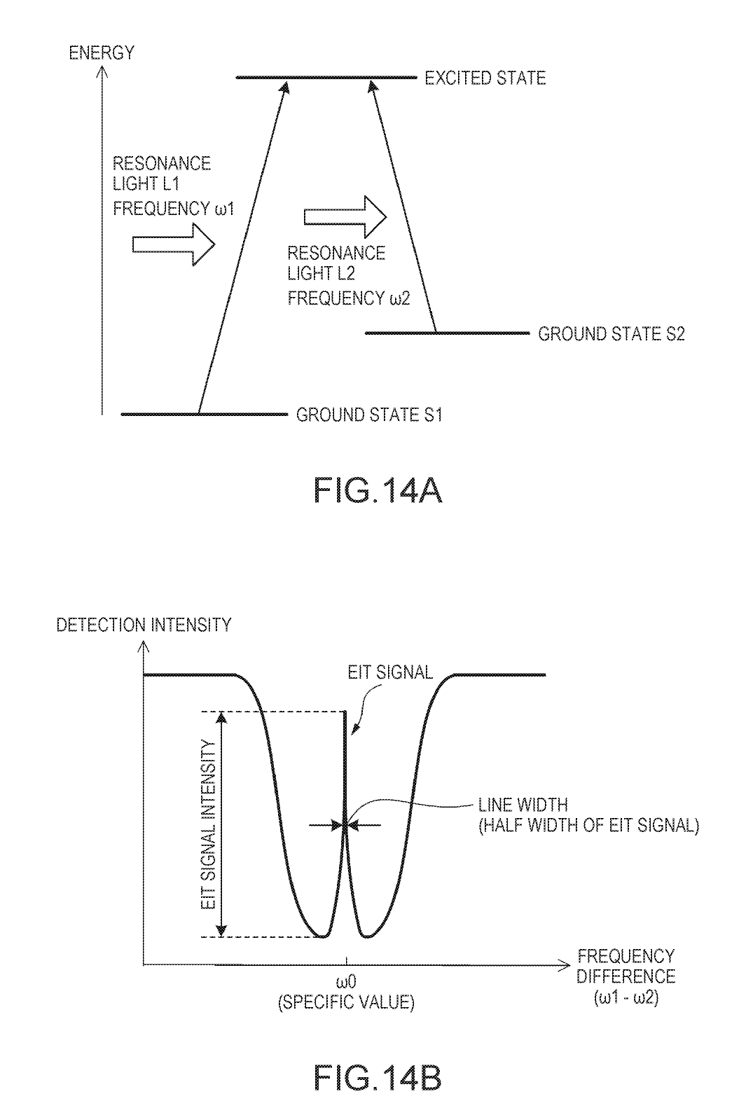

An apparatus to which the gas cells according to the above-described embodiments and modification examples can be applied is not limited to the magnetism measuring device 100. The gas cells according to the above-described embodiments and modification examples may also be applied to an atomic oscillator such as an atomic clock. FIG. 13 is a schematic view illustrating the configuration of an atomic oscillator according to Modification Example 3. FIGS. 14A and 14B are views illustrating the operation of the atomic oscillator according to Modification Example 3.

An atomic oscillator (quantum interference device) 101 according to Modification Example 3 illustrated in FIG. 13 is an atomic oscillator which uses the quantum interference effect. As illustrated in FIG. 13, the atomic oscillator 101 includes the gas cell 10 (or any one of the gas cells 10A, 10B, 50, 50A, and 57) according to the above-described embodiments, a light source 71, optical components 72, 73, 74, and 75, a light detection unit 76, a heater 77, a temperature sensor 78, a magnetic field generation unit 79, and a control unit 80.

The light source 71 emits two types of beams (resonance light L1 and resonance light L2 illustrated in FIG. 14A) having different frequencies, which will be described later, as excitation light LL for exciting alkali metal atoms in the gas cell 10. The light source 71 is formed as a semiconductor laser such as a vertical-cavity surface-emitting laser (VCSEL). The optical components 72, 73, 74, and 75 are provided between the light source 71 and the gas cell 10 on the optical path of the excitation light LL and are arranged in the order of the optical component 72 (lens), the optical component 73 (polarizing plate), the optical component 74 (neutral-density filter), and the optical component 75 (λ/4 wave plate) in a direction from the light source 71 side toward the gas cell 10 side.

The light detection unit 76 detects the intensity of the excitation light LL (the resonance light L1 and L2) transmitted through the inside of the gas cell 10. The light detection unit 76 is formed as, for example, a solar cell or photodiode and is connected to an excitation light control unit 82 of the control unit 80, which will be described later. The heater 77 (heating unit) heats the gas cell 10 to allow the alkali metal in the gas cell 10 to be maintained in a gas phase (as the alkali metal gas 13). The heater 77 (heating unit) is formed as, for example, a heating resistor.

In order to control the amount of heat generated by the heater 77, the temperature sensor 78 detects the temperature of the heater 77 or the gas cell 10. The temperature sensor 78 is formed as various well-known temperature sensors such as a thermistor or a thermocouple. The magnetic field generation unit 79 generates a magnetic field in which a plurality of degenerate energy levels of the alkali metal in the gas cell 10 are split by the Zeeman effect. Due to the Zeeman splitting, the gaps between the different degenerate energy levels of the alkali metal can be increased, resulting in an enhancement in resolution. As a result, the precision of the oscillation frequency of the atomic oscillator 101 can be increased. The magnetic field generation unit 79 is formed as, for example, a Helmholtz coil or a solenoid coil.

The control unit 80 includes the excitation light control unit 82 which controls the frequency of the excitation light LL (the resonance light L1 and L2) emitted by the light source 71, a temperature control unit 81 which controls conduction to the heater 77 on the basis of the detection result of the temperature sensor 78, and a magnetic field control unit 83 which controls a magnetic field generated by the magnetic field generation unit 79 to be constant. The control unit 80 is provided, for example, in an IC chip mounted on a substrate.

The principle of the atomic oscillator 101 is simply described. FIG. 14A is a view illustrating the energy states of the alkali metal in the gas cell 10 of the atomic oscillator 101, and FIG. 14B is a graph representing the relationship between the difference in frequency between the two beams from the light source 71 of the atomic oscillator 101 and the detection intensity detected by the light detection unit 76. As illustrated in FIG. 14A, the alkali metal (the alkali metal gas 13) sealed in the gas cell 10 has energy levels of a three-level system and may have three states including two ground states (a ground state S1, and a ground state S2) having different energy levels and an excited state. Here, the ground state S1 is a lower energy state than the ground state S2.

When the two types of resonance light L1 and L2 having different frequencies illuminate the alkali metal gas 13, the light absorbance (light transmittance) of the alkali metal gas 13 that absorbs the resonance light L1 and L2 varies according to the difference (ω1−ω2) between a frequency ω1 of the resonance light L1 and a frequency ω2 of the resonance light L2. When the difference (ω1−ω2) between the frequency ω1 of the resonance light L1 and the frequency ω2 of the resonance light L2 is coincident with a frequency corresponding to the energy difference between the ground state S1 and the ground state S2, excitation from each of the ground states S1 and S2 to the excited state stops. At this time, both of the resonance light L1 and L2 are not absorbed by the alkali metal gas 13 and is transmitted therethrough. This phenomenon is called a CPT phenomenon or an electromagnetically induced transparency (EIT) phenomenon.

The light source 71 emits the two types of beams (the resonance light L1 and the resonance light L2) having different frequencies as described above toward the gas cell 10. Here, for example, when the frequency ω2 of the resonance light L2 is changed while the frequency ω1 of the resonance light L1 is fixed, if the difference (ω1−ω2) between the frequency ω1 of the resonance light L1 and the frequency ω2 of the resonance light L2 is coincident with a frequency ω0 corresponding to the energy difference between the ground state S1 and the ground state S2, the detection intensity detected by the light detection unit 76 steeply increases as shown in FIG. 14B. This steep signal is called an EIT signal. The EIT signal has a unique value determined by the type of the alkali metal. Therefore, by using the EIT signal as a reference, the atomic oscillator 101 with high precision can be realized.

The gas cell 10 used in the atomic oscillator 101 is required to have a small size and a long service life. According to the configurations of the gas cells and the manufacturing method thereof in the above-described embodiments, the gas cell 10 having a small size and a long service life can be stably manufactured, and can be appropriately used in the atomic oscillator 101 which has a small size and a long service life with high precision.

What is claimed is:

1. A magnetism measuring device which measures a magnetic field, comprising:
a gas cell including
a cell portion which includes a first chamber, a second chamber that communicates with the first chamber and has a longitudinal direction, and an opening that is provided in the longitudinal direction of the second chamber on a side opposite to the first chamber,
a sealing portion which seals the opening, and
a gas of an alkali metal filling the first chamber and the second chamber; and
a holding portion provided in the second chamber along the longitudinal direction.

2. The magnetism measuring device according to claim 1,
wherein the holding portion has an inclined surface inclined with respect to the longitudinal direction.

3. The magnetism measuring device according to claim 1,
wherein the holding portion is formed as a recessed portion which is recessed in the longitudinal direction from a wall surface of an inner wall on a side on which the opening of the second chamber is provided.

4. The magnetism measuring device according to claim 1,
wherein the holding portion is formed as a protruding portion which extends in the longitudinal direction from a wall surface of an inner wall on a side on which the opening of the second chamber is provided.

5. A gas cell comprising:
a cell portion which includes a first chamber, a second chamber that communicates with the first chamber and has a longitudinal direction, and an opening that is provided in the longitudinal direction of the second chamber on a side opposite to the first chamber;
a sealing portion which seals the opening; and
a gas of an alkali metal filling the first chamber and the second chamber,
wherein a holding portion is provided in the second chamber along the longitudinal direction.

6. The gas cell according to claim 5,
wherein the holding portion has an inclined surface inclined with respect to the longitudinal direction.

7. The gas cell according to claim 5,
wherein the holding portion is formed as a recessed portion which is recessed in the longitudinal direction from a wall surface of an inner wall on a side on which the opening of the second chamber is provided.

8. The gas cell according to claim 5,
wherein the holding portion is formed as a protruding portion which extends in the longitudinal direction from a wall surface of an inner wall on a side on which the opening of the second chamber is provided.

9. A manufacturing method of a magnetism measuring device which measures a magnetic field, comprising:
inserting a solid containing an alkali metal through an opening along a longitudinal direction to be disposed in a second chamber of a cell portion which includes a first chamber, the second chamber that communicates with the first chamber and has the longitudinal direction, a holding portion provided in the second chamber along the longitudinal direction, and an opening that is provided in the longitudinal direction of the second chamber on a side opposite to the first chamber;
sealing the opening by a sealing portion; and
irradiating the solid with laser light,
wherein the solid is disposed in the holding portion in the inserting of the solid.

10. The manufacturing method of a magnetism measuring device according to claim 9,
wherein, in the sealing of the opening, the cell portion is disposed on the sealing portion such that the longitudinal direction follows a vertical direction and the opening is on a lower side in the vertical direction.

11. The manufacturing method of a magnetism measuring device according to claim 9,
wherein the solid is an ampoule filled with an alkali metal material, and
in the irradiating of the solid, the ampoule is irradiated with pulsed laser light with a wavelength in the ultraviolet region.

12. The manufacturing method of a magnetism measuring device according to claim 9,
wherein the solid is a pill containing an alkali metal compound and an adsorbent, and
in the irradiating of the solid, the pill is irradiated with continuous oscillating laser light with a wavelength in the infrared region with the red end.

13. A manufacturing method of a gas cell comprising:
inserting a solid containing an alkali metal through an opening along a longitudinal direction to be disposed in a second chamber of a cell portion which includes a first chamber, the second chamber that communicates with the first chamber and has the longitudinal direction, a holding portion provided in the second chamber along the longitudinal direction, and an opening that is provided in the longitudinal direction of the second chamber on a side opposite to the first chamber;
sealing the opening by a sealing portion; and
irradiating the solid with laser light,
wherein the solid is disposed in the holding portion in the inserting of the solid.

14. The manufacturing method of a gas cell according to claim 13,
wherein, in the sealing of the opening, the cell portion is disposed on the sealing portion such that the longitudinal direction follows a vertical direction and the opening is on a lower side in the vertical direction.

15. The manufacturing method of a gas cell according to claim 13,
wherein the solid is an ampoule filled with an alkali metal material, and
in the irradiating of the solid, the ampoule is irradiated with pulsed laser light with a wavelength in the ultraviolet region.

16. The manufacturing method of a gas cell according to claim 13,
wherein the solid is a pill containing an alkali metal compound and an adsorbent, and
in the irradiating of the solid, the pill is irradiated with continuous oscillating laser light with a wavelength in the infrared region with the red end.
